(19) United States
(12) Patent Application Publication
(10) Pub. No.: US 2004/0190575 A1
(43) Pub. Date: Sep. 30, 2004

(54) Lasers and methods of making them

(76) Inventors: Giorgio Ghislotti, Monteveccia (IT); Paolo Bravetti, Monza (IT); Gianluca Bacchin, I-Arese (IT)

Correspondence Address: CORNING INCORPORATED, SP-TI-3-1, CORNING, NY, 14831

(21) Appl. No.: 10/804,757

(22) Filed: Mar. 19, 2004

(30) Foreign Application Priority Data
Mar. 21, 2003 (EP) 0306479.7

(51) Int. Cl. H01S 5/00

(52) U.S. Cl. 372/45

(57) ABSTRACT

A semiconductor laser structure comprises an active laser layer of high refractive index; on each side of the active layer, a graded-index layer; on each side of the respective graded-index layer a cladding layer of low refractive index, and at least one optical trapping layer is inserted within one or each of the cladding layers. The optical trapping layer, or each of them, is thin compared with its distance from the active layer and the cladding layers have substantially the same, uniform refractive index. In consequence of this combination of features, it becomes possible to set the confinement factor by choosing only the thickness of the optical trapping layer and the divergence (VFF) by choosing only its position, within useful ranges.

### CROSS-REFERENCE TO RELATED APPLICATIONS

This application claims the benefit of priority under 35 U.S.C. § 119 of British Patent Application Serial No. 0306479.7 filed on 21 Mar. 2003.

### BACKGROUND OF THE INVENTION

1. Field of the Invention

This invention relates to semiconductor lasers and more especially (but not exclusively) to high-power semiconductor lasers suitable for optical pumping applications, and to methods of making them.

2. Technical Background

If the desired effective power output of such lasers is to be achieved, it is necessary to control the confinement factor to maintain lasing without the optical intensity, especially at the output facet of the laser, becoming high enough to risk catastrophic optical damage. It is also necessary to control the divergence of the laser light beam emerging from the laser in both significant planes (the “far field angles” and especially the “vertical far field angle” perpendicular to the layer structure of the laser) so as to achieve a reasonable match to the numerical aperture of the fibre or other light guide to which the laser output is to be coupled.

A number of semiconductor laser structures have been proposed in which one or more layers of relatively high refractive index, known as “optical trapping layers”, are introduced into the low-index cladding of the laser, spaced from the active lasing layer, so as to “dilute” the optical mode(s) with the effect that both confinement factor and divergence are reduced. For example, Iordache et al describe, in a paper in Electronics Letters vol 35 no. 2 (21 Jan. 1999) pages 148-9, a graded-index semiconductor laser structure using a single, thick optical trapping layer that relies on the use of cladding layers of very different refractive index above and below the active lasing layer. However, in general the two effects interact and it is difficult to obtain desired values for both these key characteristics at the same time.

### SUMMARY OF THE INVENTION

We have now discovered a semiconductor laser structure in which the confinement factor can be chosen, within a useful range, almost independently of divergence, so that the design of a laser to meet both requirements is greatly simplified; and in which changes in the manufacturing process, in comparison with a conventional graded-index structure, are minimised.

In accordance with the main aspect of the invention, a semiconductor laser structure comprises an active laser layer of high refractive index; on each side of the active layer, a graded-index layer; and on each side of the respective graded-index layer a cladding layer of low refractive index and at least one optical trapping layer inserted within one of the cladding layers and is characterised in that

(a) the optical trapping layer, or each of them, is thin compared with its distance from the active layer and

(b) the cladding layers have substantially the same, uniform refractive index.

For avoidance of doubt, a “graded index” layer, as used in this application, means a layer in which the refractive index changes from a high value in the part of the layer close to the active layer to a low value similar to that of the cladding layers in the part of the layer close to a cladding layer, either continuously or in a series of small steps: a layer with a constant intermediate refractive index is not included. Further, refractive indexes referred to in this application are, unless the context requires otherwise, to be measured at a wavelength of 1550 nm and a temperature of 20° C.

Preferably the graded index layer has a refractive index that changes continuously through its thickness; more especially, either a linear or a parabolic refractive index gradient is preferred.

If it is desired to locate the active layer at the centre of the optical field distribution, then there should be an optical trapping layer (or more than one such layer) inserted in each of the cladding layers, preferably in a symmetrical structure. We prefer, however, an unsymmetrical structure in which there is an optical trapping layer (or more than one such layer) inserted in the cladding layer on one side only of the active layer; more specifically, on the side that is nearer to the substrate on which the device will normally be formed. This last structure has the advantage that, once the required layers have been laid down, subsequent fabrication steps may be substantially the same as for a conventional graded-index laser without any optical trapping layer.

For simplicity and ease of fabrication, we prefer to use only one optical trapping layer, or only one on each side of the active layer; but if desired up to about three or four optical trapping layers can be used on one or on both sides; multiple layers provide additional degrees of freedom and may allow the shape of the near field profile to be accurately controlled, within limits; this, in turn, allows control of the shape and width of far field profile. The optical trapping layer(s) preferably have a refractive index equal or at least close to the highest refractive index in the graded-index layers. The refractive indexes (and so compositions) of all other parts of the laser may be the same as for a conventional graded-index laser.

The invention includes a method of making a laser in accordance with the invention comprising forming a corresponding layer structure on a substrate by epitaxial growth, applying electrodes and cleaving to form mirrors.

The layer structure may be formed by any epitaxial growth technique, for example molecular beam epitaxy, metal-organic chemical vapour deposition, metal-organic molecular beam epitaxy or chemical beam epitaxy.

The method of the invention may include other conventional steps, and all steps after the formation of the layer structure may be entirely conventional. Usually pattern etching will be used to form a ridge in order to confine injected charge-carriers and so improve efficiency of light emission, and in such cases a patterned deposit of silicon nitride will usually be used to control the deposition of metal to form electrodes. Other potentially useful steps include lapping the underside of the substrate after processing of the top surface is complete to reduce its thickness and thermal resistance; facet passivation to increase durability; and deposition of oxides on the facets to adjust reflectivity.

In the laser structures of the invention, for predetermined refractive index values, the confinement factor is almost determined by the thickness of the optical trapping layer(s) and almost independent of the spacing of the optical trapping layers from the active layer, for most of the practicable range of these dimensions; for part (only) of that range, the divergence is almost determined by the spacing and almost independent of thickness.

It will be appreciated that changes in refractive index of the various parts of the laser will have a significant effect on the confinement factor and divergence; some examples will be reported below, and on the basis of our present experience, we believe that changes that might be seriously considered will usually have an effect very similar to the effect of a change in the thickness of the optical trapping layer. Those skilled in the art will be able to determine the effect of proposed changes by routine experiments or by computation.

Additional features and advantages of the invention will be set forth in the detailed description which follows, and in part will be readily apparent to those skilled in the art from that description or recognized by practicing the invention as described herein, including the detailed description which follows, the claims, as well as the appended drawings.

It is to be understood that both the foregoing general description and the following detailed description present embodiments of the invention, and are intended to provide an overview or framework for understanding the nature and character of the invention as it is claimed. The accompanying drawings are included to provide a further understanding of the invention, and are incorporated into and constitute a part of this specification. The drawings illustrate various embodiments of the invention, and together with the description serve to explain the principles and operations of the invention.

### BRIEF DESCRIPTION OF THE DRAWINGS

The invention will be further described, by way of example, with reference to the accompanying drawings in which:

FIG. 1 is a diagrammatic representation of the layer structure of a first form of laser in accordance with the invention;

FIGS. 2 and 3 are graphs showing respectively the computed confinement factor and vertical far field angle as a function of the thickness and spacing of the optical trapping layers for a range of lasers differing only in dimensions from that of FIG. 1;

FIGS. 4 and 5 are diagrams, similar to FIG. 1, showing alternative layer structures for lasers in accordance with the invention;

FIG. 6 is a sketch of a laser in which the layer structure corresponds to FIG. 4 and FIGS. 7-9 are successively enlarged details thereof;

FIGS. 10-11 and 12-13 are graphs, each pair corresponding to FIGS. 2 and 3 respectively, illustrating the effect of changing the composition, and therefore the refractive index, of the optical trapping layers in the structure of FIG. 1; and

FIGS. 14-15 are graphs, corresponding to FIGS. 2 and 3 respectively, illustrating the effect of changing the profile of the graded-index layers in the structure of FIG. 1.

### DETAILED DESCRIPTION OF PREFERRED EMBODIMENTS

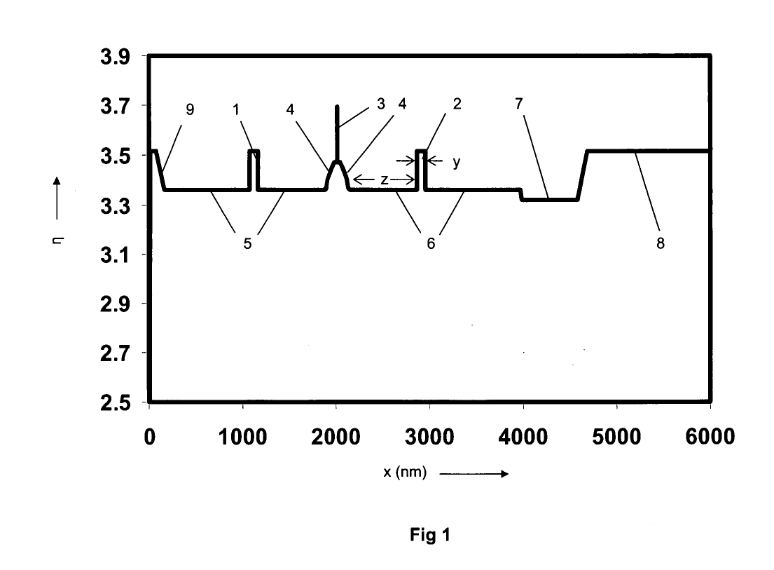

FIG. 1 represents by plotting refractive index η against the distance x from the free surface the layer structure of a laser in accordance with the invention which is symmetrical in the sense that it has two optical trapping layers 1, 2 equally spaced from the active layer 3. The active layer may be of the single-, double- or multiple-quantum well type, and need not be further described as it is conventional in each case. Around it aluminium gallium arsenide and gallium arsenide are used to make the required layer structure, the content (if any) of aluminium being varied in the usual way to obtain the required refractive index, as represented in the diagram, and energy levels.

Immediately adjacent to each side of the active layer is a layer 4 in which the refractive index (as defined above) gradually reduces from 3.52 (at zero aluminium content) to about 3.36 (at an aluminium content about 27.5 atom %) with a profile more or less approximating a parabola with its vertex at zero aluminium so as to establish a graded-index separate-confinement heterostructure (GRIN-SCH), and, apart from the optical trapping layers 2, 3 which each have a refractive index of about 3.52 (zero aluminium), the low index of 3.36 (27.5 atom % aluminium) is maintained throughout cladding layers 5, 6. An optional layer 7 of ultra-low refractive index (say η=3.32, 35 atom % aluminium content) may be used to inhibit coupling of light into the substrate 8 (only a small part of which is included in the figure). Preferably the refractive index is graded as shown between layer 7 and substrate 8 to avoid an abrupt interface between two materials with different bandgap, that would raise the value of voltage required to drive the laser (in fact the presence of an optical trapping layer slightly increases this voltage). A graded high-index surface layer 9 provides for a good ohmic electric contact.

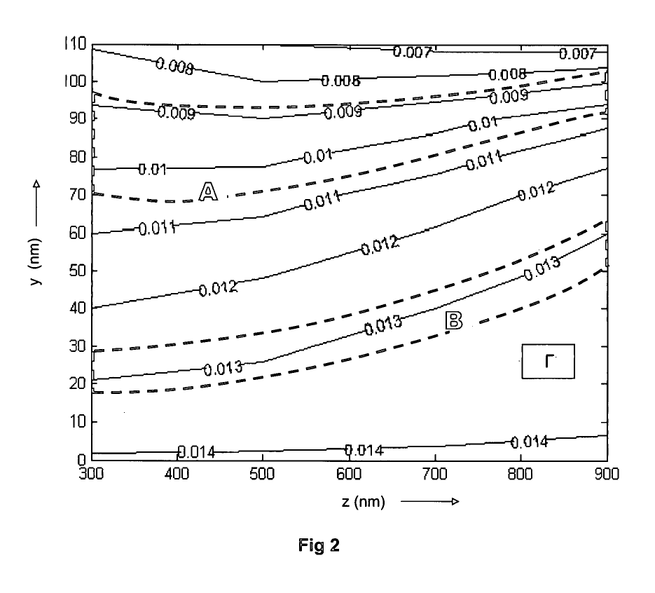

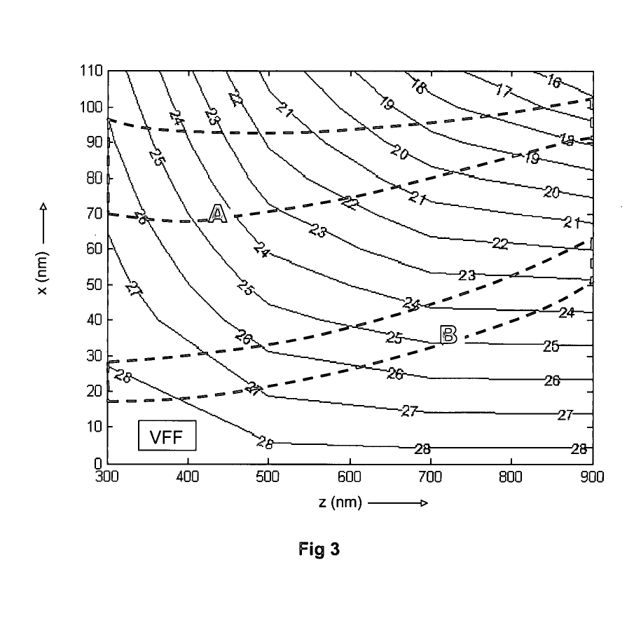

FIG. 2 plots the computed confinement factor Γ for a 60 μm broad-area laser made with a layer structure generally according to FIG. 1 but with varying thickness y of the optical trapping layers in the range up to 110 nm and varying distances z of the optical trapping layer from the nearest boundary of the respective graded-index layer 4 in the range from 300 to 900 nm.

Similarly, FIG. 3 plots the computed vertical far field angle (VFF) for the same range of dimensions. In this context, “vertical” means in the direction normal to the planes of the layer structure, and the computation was on the basis of the full width of the radiation lobe at half its maximum intensity (FWHM).

It will be apparent from inspection of FIGS. 2 and 3 that it is possible, by choosing a combination of thickness and distance within Area A marked on the figures, or to a good approximation just by choosing a thickness y of about 85 nm, a low confinement factor of 0.010 can be obtained, and that by choosing an appropriate distance z, any desired VFF in the approximate range 15-35° can be obtained. Similarly, by choosing a combination of dimensions in Area B, or to a fair approximation by choosing a thickness y of 35 nm, it is possible to obtain a high confinement factor of about 0.013 and by appropriate choice of distance z to combine it with any desired VFF in the approximate range 10-22°.

The numerical values associated with FIGS. 2 and 3 are, of course, specific to the refractive index values of FIG. 1, but the principles hold true for other practicable values, as will be further illustrated below.

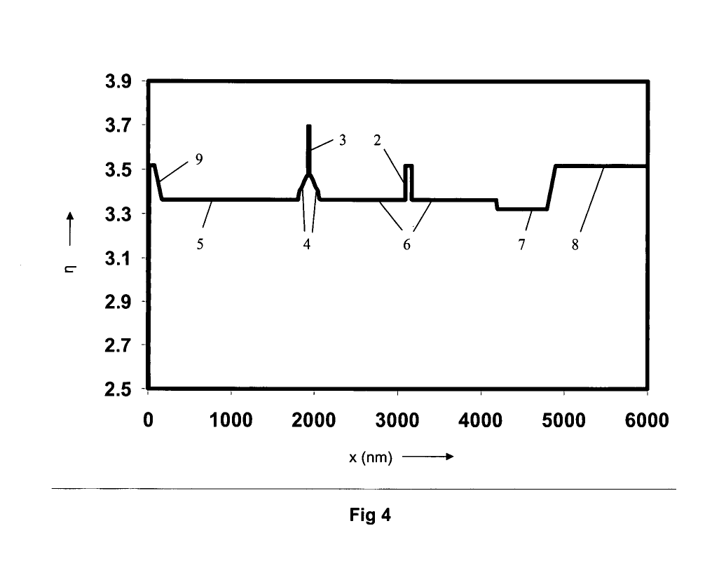

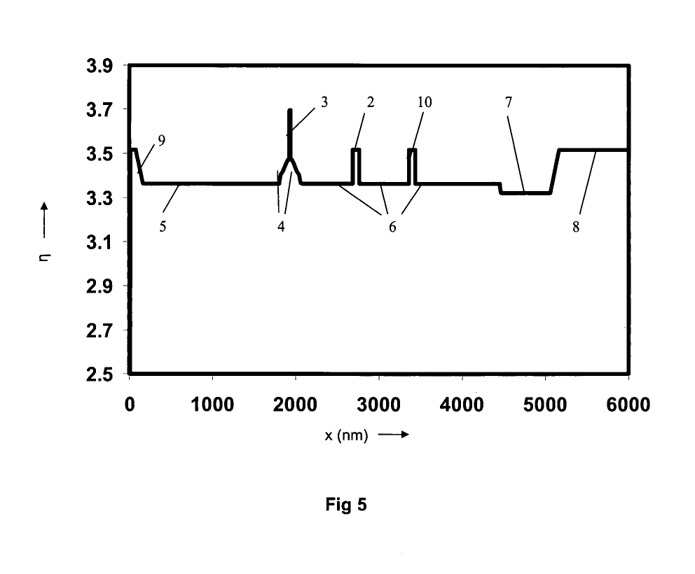

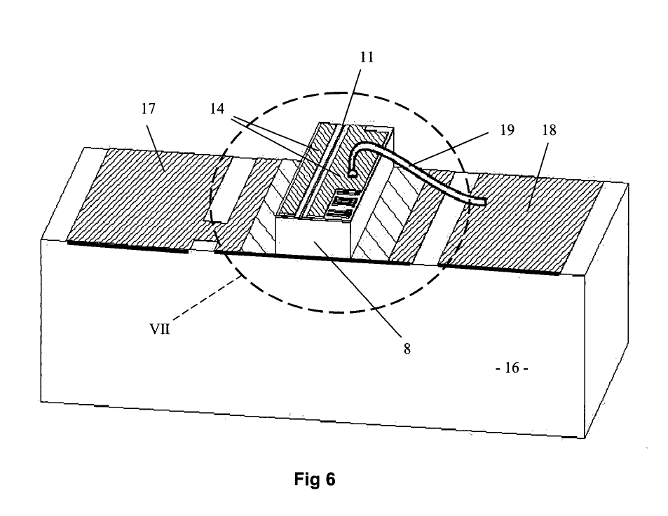

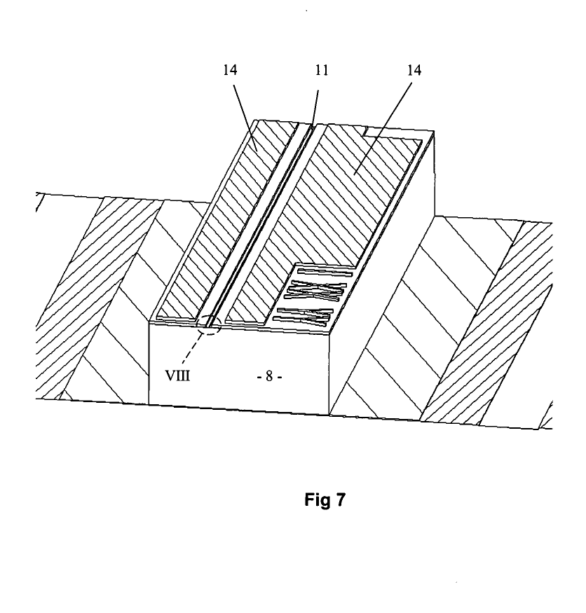

FIGS. 4 and 5 show alternative structures in accordance with the invention that are asymmetrical in the sense that they have optical trapping layers on one side only. The structure of FIG. 4 is substantially the same as that of FIG. 1 except that the optical trapping layer 1 is omitted, and the structure of FIG. 5 is substantially the same as that of FIG. 4 except that an additional optical trapping layer 10 is added. Third or even fourth such layers could be added if desired, though this may require an increased cladding thickness, preferably on the underside only. Additional layers can shape the near field as desired, in order, for instance, to reduce the far field side lobes.

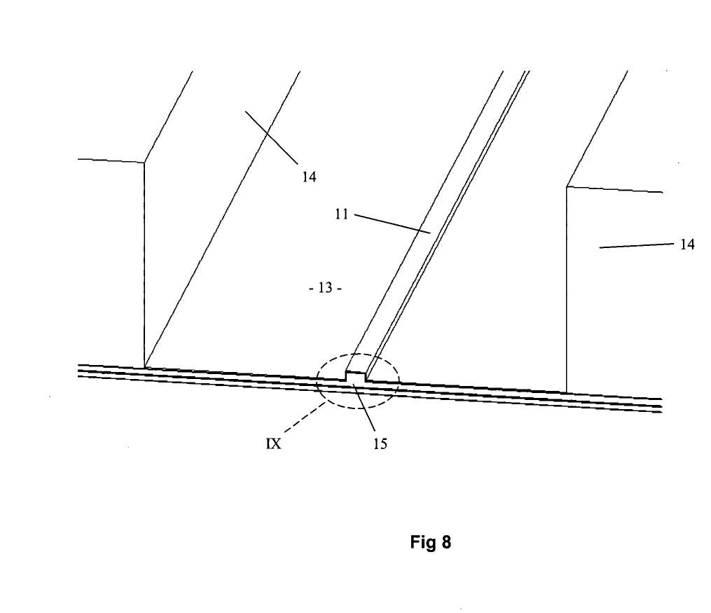

FIGS. 6-9 show in diagrammatic perspective the actual structure of a raised-ridge laser that is represented by FIG. 4, FIGS. 7, 8 and 9 being enlarged details of the parts indicated by the ovals indicated at VII, VIII and IX respectively in the preceding Figure. These figures will be best understood in the reverse order.

FIG. 9 shows the cladding layers 5, 6 and 7, graded index layers 4, active layer 3, optical trapping layer 2 and graded high-index layer 9 previously described. It also shows the laser ridge 11 with a cap layer 12 of highly doped gallium arsenide, an insulating coating 13 of silicon nitride on the sides of the ridge and the adjacent etched-back surfaces, and a coating 13 of titanium/platinum/gold alloy extending over the whole upper surface.

On top of this coating 13 (FIG. 8) are electrolytically deposited gold contact pads 14 for the positive electric connection. One of the laser facets 15 can be seen in this Figure. This structure is supported on a substrate 8 and together with it constitutes a laser chip, which in its turn is set on a sub-mount 16 providing separate contact areas 17 and 18. The negative contact area 17 is directly connected to the base of the substrate 8 by welding, and the positive contact area 18 connected to the pads 14 by a soldered lead 19.

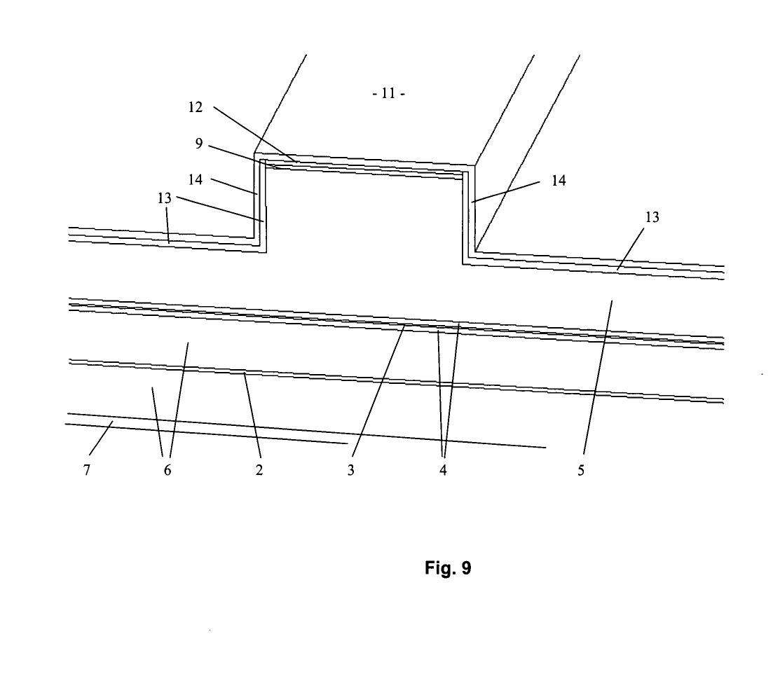

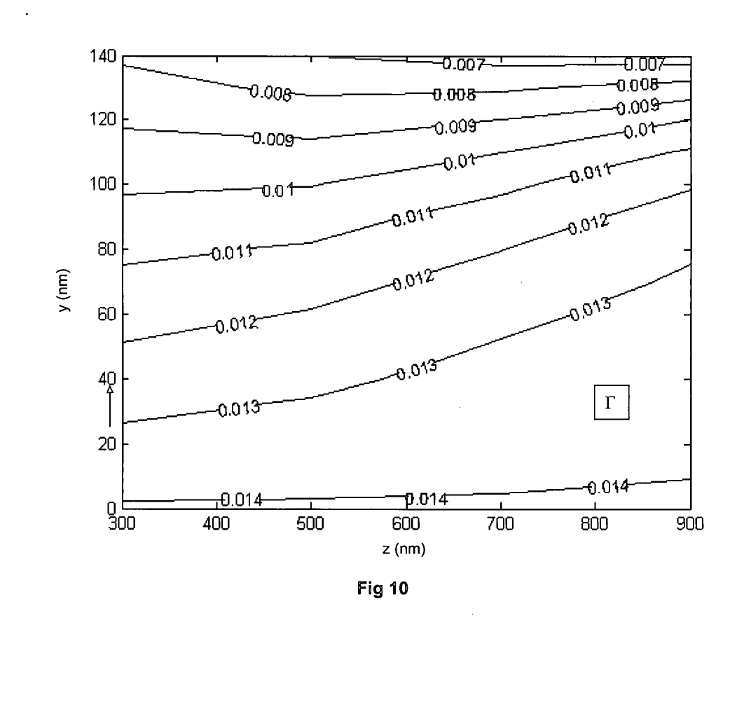

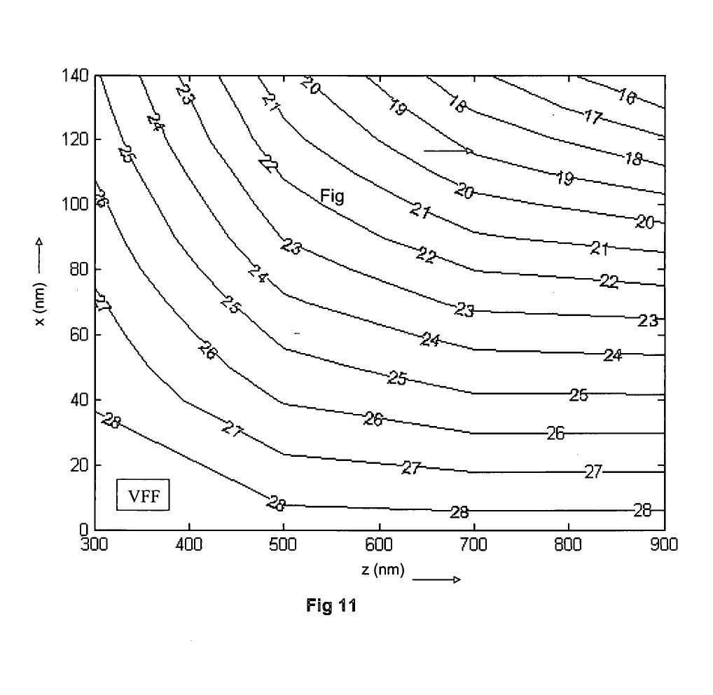

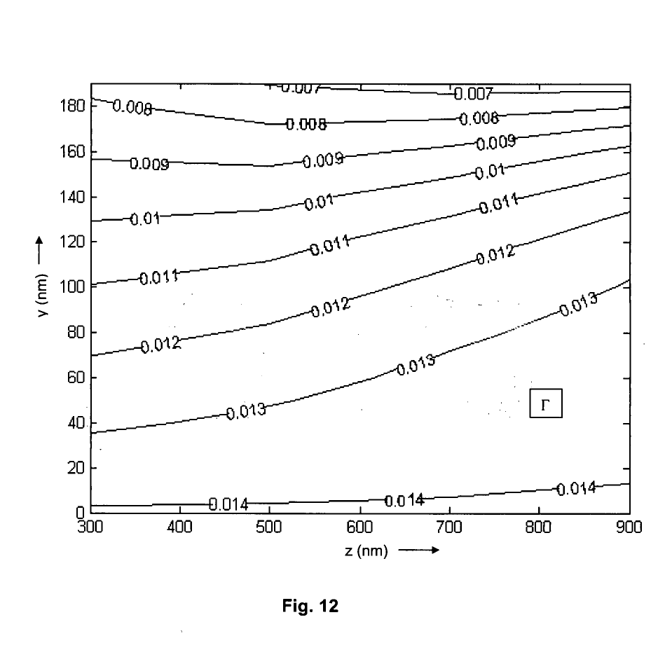

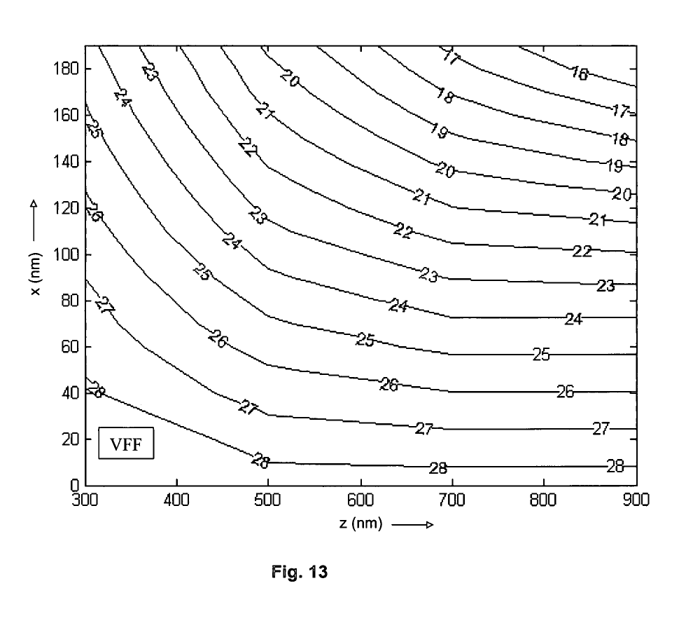

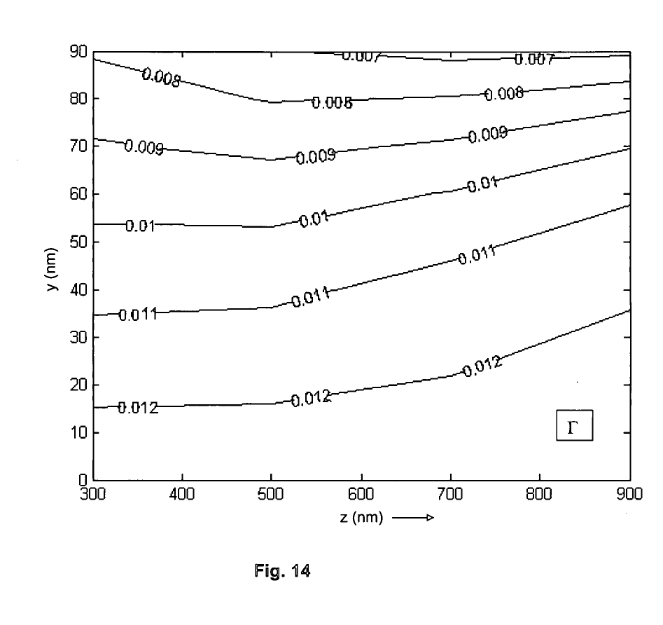

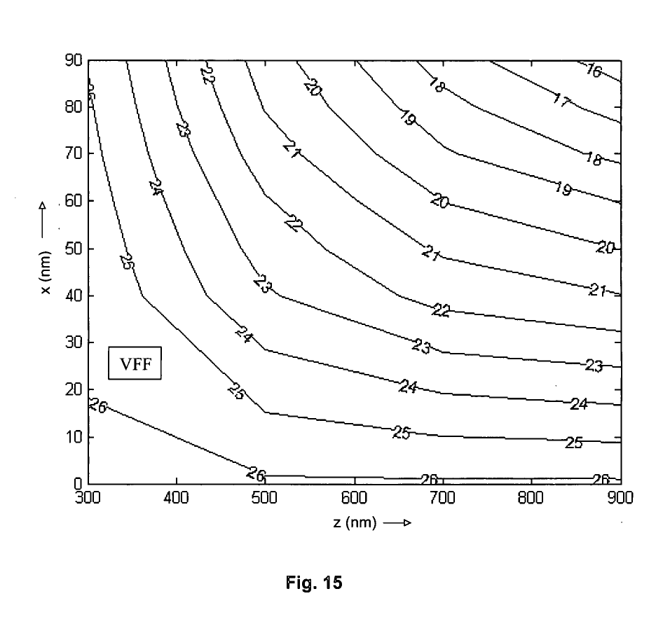

FIGS. 10, 12 and 14 correspond to FIG. 2 and show results computed for three variant structures; FIGS. 11, 13 and 15 similarly correspond to FIG. 3 and represent the same structures. In each case, the vertical scale has been chosen to make immediately obvious the very close similarity of the corresponding figures. FIGS. 7 and 8 are based on a structure differing from FIG. 1 only in having the optical trapping layers made of a gallium-aluminium arsenide with 5% aluminium (η about 3.49); FIGS. 9 and 10 on a similar modification with 10% aluminium (η about 3.46), and FIGS. 11 and 12 on a modification of FIG. 1 with linear instead of parabolic profile in the graded index layers 4, 4.

Layer structures generally according to FIGS. 1, 4 and 5 were made by molecular beam epitaxy techniques, as was a structure similar to that of FIG. 5 but with three optical trapping layers equally spaced on the same side of the graded-index heterostructure. From each structure, a 60 μm-wide by 1.5 mm long broad area laser and a 4 μm-wide, 2 mm long raised-ridge laser were made by a conventional process.

For the raised-ridge laser, the ridge was first defined by photolithography and chemical etching, and a photoresist layer is deposed and patterned such that it remains only on top of the ridge. A coating of silicon nitride was then applied overall and removed from above the ridge by a “lift-off” process in which an acid etch solution penetrates the silicon nitride layer to remove the photoresist and that part of the silicon nitride that overlies it. Silica was applied to the top surface area, and a photoresist was applied and patterned to form a mask that defines the area of the positive electrode. The area exposed by the mask was subjected to reactive ion etching to remove silica from it and after surface preparation titanium, platinum and gold were successively applied by vapour deposition, and the remaining silica together with the part of the deposited metal on top of it removed by wet etching. A further similar coating of photoresist was used to cover the ridge area and leave uncovered the electrode area on both sides of the ridge where two thick gold pads where then grown by electrolytic deposition. At this stage the thickness of the chip was reduced by lapping and chemical etching the underside to obtain dimensions appropriate to the thermal resistance and capacitance required. A negative electrode and reinforcement were successively applied to the underside by vapour deposition, and the facets exposed by cleaving, passivated and coated with oxides for the control of reflection. Multiple lasers were being formed on the chip, and they were now separated by cleaving and appropriately packaged.

The preparation of the broad-area laser was similar, with the omission of some of the steps (such as ridge etching, facet passivation, reflection control, etc.).

A pair of conventional GRIN-SCH lasers, substantially identical except for the omission of the optical trapping layers, were made for comparison.

In each case, the confinement factor and VFF were measured for comparison with computed values, and the threshold current density Jₜₕ, internal loss aᵢ and characteristic temperature T₀ were measured, all of these for the broad-area laser, while the slope efficiency was measured for the more realistic raised ridge laser. Results of the measurements are shown in the following Table:

| | Example | | | | | | | |
|---|---|---|---|---|---|---|---|---|
| | A^{#} | 1 | 2 | 3 | 4 | 5 | 6 | 7 |
| related figure | none | | | | | | | none |
| OTL thickness | — | 80 | 80 | 60 | 70 | 90 | 70, | 80, |
| (mm) | | | | | | | 60 | 70, |
| | | | | | | | | 60 |
| OTL spacing* | — | 700 | 900 | 700 | 1000 | 1200 | 600, | 700, |
| (mm) | | | | | | | 600 | 700, |
| | | | | | | | | 700 |
| Γ (‰) (simulated) | 13.0 | 10.4 | 11.5 | 12.6 | 12.7 | 11.7 | 10.5 | 9.7 |
| Γ (‰) | 13.0 | 8.9 | 9.3 | 11.5 | 12.0 | 11.3 | 8.5 | 9.1 |
| (measured) | | | | | | | | |
| VFF (°) | 27.5 | 21.4 | 19.5 | 24.8 | 22.3 | 18.6 | 21.1 | 15.1 |
| (simulated) | | | | | | | | |
| VFF (°) | 27.7 | 20.8 | 21.2 | 25.1 | 22.0 | 18.4 | 21.0 | 15.4 |
| (measured) | | | | | | | | |
| Jₜₕ (A cm⁻²) | 128.2 | 170.9 | 155.8 | 169.2 | 130.4 | 197.8 | 183.7 | 152.9 |
| aᵢ (cm⁻¹) | | | | | | | | |
| T₀ (K)(750) | 151.7 | 134.9 | 144.7 | 148.5 | 170.5 | 134.2 | 151.7 | 155.0 |
| Slope Efficiency | 0.856 | 0.783 | 0.763 | 0.839 | 0.839 | 0.784 | 0.802 | 0.759 |

^{#}conventional GRIN-SCH for comparison
*for the first OTL, measured from the GRIN-SCH; for any subsequent OTL, from the previous one

It will be apparent to those skilled in the art that various modifications and variations can be made to the present invention without departing from the spirit and scope of the invention. Thus it is intended that the present invention cover the modifications and variations of this invention provided they come within the scope of the appended claims and their equivalents.

What is claimed is:

1 A semiconductor laser structure comprising an active laser layer of high refractive index; on each side of the active layer, a graded-index layer; and on each side of the respective graded-index layer a cladding layer of low refractive index and at least one optical trapping layer inserted within one of the cladding layers wherein:
(a) said at least one optical trapping layer, is thin compared with its distance from said active layer and
(b) said cladding layers have substantially the same, uniform refractive index.

2 A semiconductor laser structure as claimed in claim 1 in which said graded index layer has a refractive index that changes continuously through its thickness.

3 A semiconductor laser structure as claimed in claim 1 in which said graded index layer has a refractive index that changes according to a linear refractive index gradient through its thickness.

4 A semiconductor laser structure as claimed in claim 1 in which said graded index layer has a refractive index that changes according to a parabolic refractive index gradient through its thickness.

5 A semiconductor laser structure as claimed in claim 1 in which there is at least one said optical trapping layer inserted in the said cladding layer on the side of the active layer that is nearer to a substrate on which the device is formed.

6 A semiconductor laser structure as claimed in claim 1 in which said at least one optical trapping layer has a refractive index about equal to the highest refractive index in said graded-index layers.

7 A method of making a laser comprising forming on a substrate by epitaxial growth a layer structure comprising:
an active laser layer of high refractive index; on each side of the active layer,
a graded-index layer; and on each side of the respective graded-index layer
a cladding layer of low refractive index and at least one optical trapping layer inserted within one of the cladding layers wherein:
(a) said at least one optical trapping layer, is thin compared with its distance from said active layer and
(b) said cladding layers have substantially the same, uniform refractive index; applying electrodes and cleaving to form mirrors.

8 A method as claimed in claim 7 in which said layer structure is formed by a technique selected from molecular beam epitaxy, metal-organic chemical vapour deposition, metal-organic molecular beam epitaxy and chemical beam epitaxy.

9 A method as claimed in claim 7 including the step of pattern etching to form a ridge.

10 A method as claimed in claim 7 in which the applying of electrodes comprises the use of a patterned deposit of silicon nitride.
